(19) United States
(12) Patent Application Publication
(10) Pub. No.: US 2006/0049422 A1
(43) Pub. Date: Mar. 9, 2006

(54) Surface mount LED

(76) Inventor: Iwao Shoji, Tokyo (JP)

Correspondence Address: CERMAK & KENEALY, LLP, 515 EAST BRADDOCK RD SUITE B, Alexandria, VA, 22314, US

(21) Appl. No.: 11/214,805

(22) Filed: Aug. 31, 2005

(30) Foreign Application Priority Data
Aug. 31, 2004 (JP) 2004-251240

(51) Int. Cl. H01L 33/00

(52) U.S. Cl. 257/100

(57) ABSTRACT

An LED can include a silicon substrate that has a conductive pattern including an LED chip equipped portion, a connection portion, and external electrodes. A glass frame can be anodic-bonded onto the silicon substrate, and can include a through-hole forming a lamp house. An LED chip can be mounted onto the silicon substrate in the through-hole of the glass frame, and a mold portion made of silicone resin can be filled into the through-hole of the glass frame.

This application claims the priority benefit under 35 U.S.C. § 119 of Japanese Patent Application No. 2004-251240 filed on Aug. 31, 2004, which is hereby incorporated in its entirety by reference.

### BACKGROUND OF THE INVENTION

1. Field of the Invention

The present invention relates to an LED, and more particularly to an LED molded with a transparent resin surrounding an LED chip.

2. Description of the Related Art

Conventionally, an LED has been configured as shown in FIGS. 9A and 9B to FIGS. 11A and 11B, for example.

In FIGS. 9A and 9B, an LED 1 includes a rigid substrate 2, an LED chip 3 mounted on the rigid substrate 2, and a resin mold portion 4 formed on the rigid substrate 2, surrounding the LED chip 3.

The rigid substrate 2 is provided with a conductive pattern (not shown) constituting a predefined circuit on the surface thereof and the conductive pattern turns around to the backside of the rigid substrate 2 to constitute electrodes 2a, 2b (see FIG. 9B) for external connection.

The LED chip 3 is an LED chip with a known configuration, for which die bonding is performed onto a chip mount portion of the rigid substrate 2 and wire bonding (not shown) is performed for connection to an adjacent connection land. The resin mold portion 4 is made of a transparent material such as epoxy resin and is formed on the rigid substrate 2 by a method such as a transfer mold, such that the LED chip 3 is surrounded.

In accordance with the LED 1 having such a configuration, by applying an activation voltage to the LED chip 3 via electrodes 2a, 2b externally, the LED chip 3 is activated to emit light. The light from the LED chip 3 is emitted to the exterior of the LED with a light distribution property of the so-called Lambertian distribution due to the lens effect of the resin mold portion 4.

In FIGS. 10A and 10B, an LED 5 includes a housing 7 to which a lead frame 6 is insert-molded and a lamp house 7a is formed by a recess provided in the center of the surface of the housing 7.

Then, after the LED chip 3 is mounted on one (1) lead frame 6a exposed in the lamp house 7a, wire bonding of the LED chip 3 is performed to another lead frame 6. Subsequently, after the lamp house 7a is filled with a transparent material such as silicone resin, the LED 5 is completed by bending each lead frame (so-called forming) to form electrodes turning around to the backside of the housing 7.

In accordance with the LED 5 with such a configuration, similarly, by applying an activation voltage to the LED chip 3 via electrodes on the backside of the housing 7 externally, the LED chip 3 is activated to emit light. The light from the LED chip 3 is reflected by the surface of the lamp house 7a such that it emits to the outside with a predetermined light distribution property.

In FIGS. 11A and 11B, an LED 8 includes a housing 7 with a lead frame 6 integrally formed in MID in a similar manner, and a lamp house 7a is formed by a recess provided in the center of the surface of the housing 7. After the LED chip 3 is mounted on one (1) lead frame 6a exposed in the lamp house 7a, wire bonding of the LED chip 3 is performed to another lead frame 6. Then, the LED 8 is completed by filling the lamp house 7a with a transparent material such as silicone resin.

In the LED 8 with such a configuration, by applying an activation voltage to the LED chip 3 via portions of the lead frame 6 (electrodes) exposed externally on the backside of the housing 7, the LED chip 3 is activated to emit light. The light from the LED chip 3 is reflected by the surface of the lamp house 7a such that it emits to the outside with a predetermined light distribution property.

However, the LEDs 1, 5, 8 with configurations as described above have the following problems. Although the LED 1 does not have a lamp house and is configured as a light source having the so-called Lambertian distribution, if a larger LED chip 3 is used or if a plurality of LED chips 3 are mounted, an occupied area of the LED chip 3 is increased, and distortions such as cracks and warpage can be generated in the resin mold portion 4 by stress of the transparent material (e.g., epoxy resin), which makes it difficult to maintain quality.

Also, since the thermal conductivity of the rigid substrate 2 is relatively low and it is difficult to conduct heat due to the attachment of the LED chip 3 to the mount substrate, the temperature of the LED chip 3 increases and luminous efficiency is reduced.

Further, if the resin mold portion 4 is constituted by epoxy resin, when the LED chip 3 generates light with a short wavelength (e.g., ultraviolet light), the resin mold portion 4 can deteriorate by absorption of photons.

In the LED 5, the heat generated by the LED chip 3 can be conducted efficiently to the mount substrate via the lead frame 6. However, since the manufacturing method includes processes such as insert molding, die bonding and wire bonding of the LED chip, the material for the housing 7 must be resin which can be used at high temperatures. Thus, it is often unavoidable to use opaque resin with heat resistance (e.g., for example, LCP, PPA and the like as engineering plastics), which makes it difficult to obtain the light distribution property of the Lambertian distribution and which may not conform to predefined optical systems in some cases.

In the LED 8, LCP, PPA or the like described above is used as the resin enabling MID. Thus, the LED 8 may not conform to predefined optical systems in a similar way.

### SUMMARY OF THE INVENTION

In view of the above and other situations and problems that currently exist in the art, one of the many aspects of the invention is providing an LED from which the light distribution property of the Lambertian distribution can be obtained and which does not generate distortions such as cracks and warpage due to stress of a lens portion even if the occupied area of the LED chip is increased.

According to another aspect of the invention there is provided an LED that can include a silicon substrate that has a conductive pattern including an LED chip equipped portion, a connection portion and external electrodes. A glass frame can be anodic-bonded onto the silicon substrate, and can include a through-hole forming a lamp house. An LED chip can be mounted onto the silicon substrate in the through-hole of the glass frame, and a mold portion consisting of or including silicone resin can be filled into the through-hole of the glass frame.

The LED can be a surface mount type LED and the silicon substrate can be provided with the external electrodes on a side face or a laterally-facing slant face thereof.

The silicon substrate can be provided with a trapezoidal diaphragm surface and the diaphragm surface provided with the external electrodes. In addition,the silicone resin constituting the mold portion can have a refraction index close to the refraction index of the glass frame, and the glass frame can be constituted by borosilicate glass.

The conductive pattern formed on the silicon substrate can be provided with a portion that constitutes an additional predetermined circuit.

A wavelength conversion material (e.g., fluorescent material) can be dispersedly mixed in the silicone resin constituting the mold portion. In addition, a diffusing agent can also be mixed in the silicone resin constituting the mold portion.

In operation, according to the above-described configurations, light is emitted from the LED chip by applying an activation current to the LED chip. The light emitted from the LED chip can be emitted omnidirectionally to the outside on the side of the silicon substrate surface, directly via the mold portion filled in the through-hole of the glass frame, or via the glass frame.

In this case, since a lamp house is formed by glass with high optical transparency or, preferably, borosilicate glass, a conventional heat-resistance opaque material is not needed to be used. In addition, since the light emitted from the LED chip may be efficiently emitted in a lateral direction via the glass frame, the light distribution property of the so-called Lambertian distribution can be obtained.

Also, since the mold portion in this example is constituted by silicone resin, stress of the silicone resin is relatively small and therefore, generation of distortions such as cracks and warpage may be reduced. In addition, deterioration of the mold portion may be eliminated if the LED chip generates light with a short wavelength (e.g., ultraviolet light).

Further, since a silicon substrate can be used as a substrate, which has relatively high thermal conductivity, heat generated by the activation of the LED chip can be efficiently conducted via the silicon substrate to, for example, the mount substrate, and luminous efficiency is not reduced due to the increased temperature of the LED chip.

If the silicon substrate is provided with external electrodes on the backside thereof, an LED may be surface-mounted by connecting these electrodes to a connection land formed on the surface of the mount substrate. If the silicon substrate is provided with external electrodes on a side face or a laterally-facing slant face, since the external electrodes face a lateral direction instead of the upward direction, the external electrodes can easily be connected by soldering or the like even if the silicon substrate and the LED are configured to be small.

If the silicon substrate is provided with a trapezoidal diaphragm surface and if the diaphragm surface is provided with external electrodes, the diaphragm surface may be mounted onto the mount substrate by various methods, such as soldering, or by pressure-bonding to a connection land of the mount substrate under a buckling force of the silicon substrate itself.

If silicone resin constituting the mold portion has a refraction index close to the refraction index of the glass frame, when the light emitted from the LED chip enters into the glass frame via the mold portion, the light may be transmitted through the glass frame substantially without generating reflection and refraction at the interface between the mold portion and the glass frame. Therefore, the light-extraction efficiency can be improved in the lateral direction.

As indicated above, the conductive pattern formed on the silicon substrate can be provided with a portion constituting a predetermined circuit. For example, a device such as the Zener diode can be created on the silicone substrate by impurity diffusion. In the case where a Zener diode is created on the silicon substrate, by applying an external activation voltage to the LED chip via the Zener diode, an excessive voltage is prevented from being applied to the LED chip and the LED chip can be protected.

When a wavelength conversion material (e.g., fluorescent material) is dispersedly mixed in the silicone resin constituting the mold portion, the light emitted from the LED chip enters into the wavelength conversion material that is dispersed and mixed in the silicone resin constituting the mold portion, and thereby, the wavelength conversion material is excited and emits excitation light. Thus, the light emitted from the LED includes a mixed color of the light emitted from the LED chip and the excitation light from the wavelength conversion material. The mixed color light can be emitted to the outside directly from the mold portion or via the glass frame, and the emitted light will have a wavelength different from the light emitted directly from the LED chip. Thus, white light can be obtained, for example, by mixing colors of blue light from the LED chip and yellow light of the excitation light.

If a diffusing agent is mixed in the silicone resin constituting the mold portion, the light emitted from the LED chip enters into the diffusing agent and is diffused. In this way, the light distribution property of the LED chip itself can be made uniform as a whole and, especially if a plurality of LED chips is provided, an entirely uniform light distribution property can be obtained because the light from each LED chip is diffused by the diffusing agent.

In this way, an LED can be configured such that the light distribution property of the Lambertian distribution can be obtained and such that distortions such as cracks and warpage are not generated due to the stress of the lens portion even if the occupied area of the LED chip is increased.

### BRIEF DESCRIPTION OF THE DRAWINGS

The above and other aspects, features and advantages of the invention will become more apparent from the following detailed description when taken in conjunction with the accompanying drawings, in which:

FIG. 1 is a schematic perspective view showing a configuration of an embodiment of an LED made in accordance with the principles of the invention, viewed obliquely from above;

FIG. 2 is a schematic perspective view of the LED shown in FIG. 1, viewed obliquely from beneath;

FIGS. 3A and 3B are schematic perspective views of a silicon substrate used with the LED of FIG. 1, viewed obliquely from above and viewed obliquely from beneath, respectively;

FIG. 4 is a schematic perspective view of a glass frame used with the LED of FIG. 1;

FIG. 5 is a schematic perspective view showing a configuration of another embodiment of the LED made in accordance with the principles of the invention, viewed obliquely from above;

FIG. 6 is a schematic perspective view showing a configuration of another embodiment of the LED made in accordance with the principles of the invention, viewed obliquely from above;

FIGS. 7A and 7B are an exploded perspective view before bonding and a perspective view after bonding, respectively, of the silicon substrate used with the LED of FIG. 6;

FIGS. 8A and 8B are a schematic perspective view and an equivalent circuit diagram of a principal part, respectively, showing a configuration of another embodiment of the LED made in accordance with the principles of the invention;

FIGS. 9A and 9B are a plain view and a side view, respectively, showing a configuration of an example of an LED using a conventional rigid substrate;

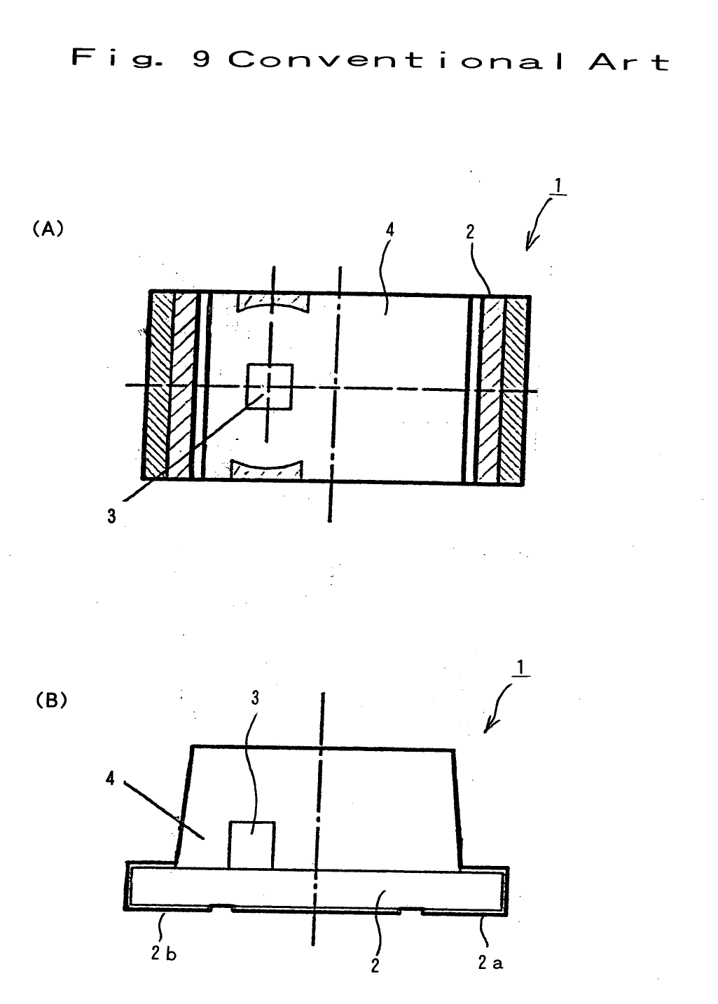

FIGS. 10A and 10B are a plain view and a side view, respectively, showing a configuration of an example of an LED into which a conventional lead frame is insert-molded; and

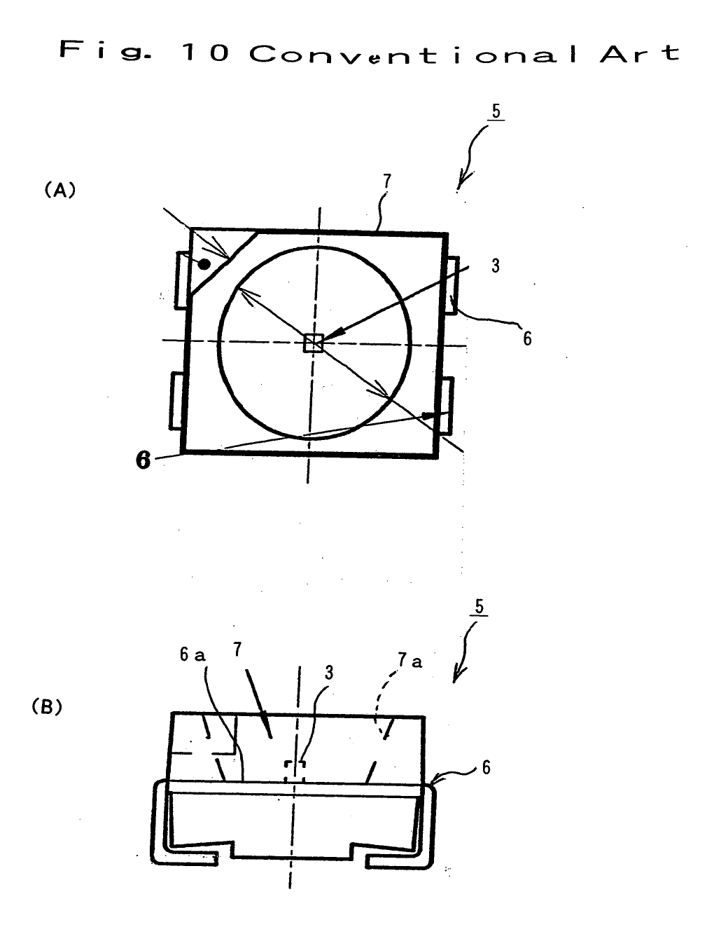

FIGS. 11A and 11B are a plain view and a side view, respectively, showing a configuration of an example of an LED formed by conventional MID.

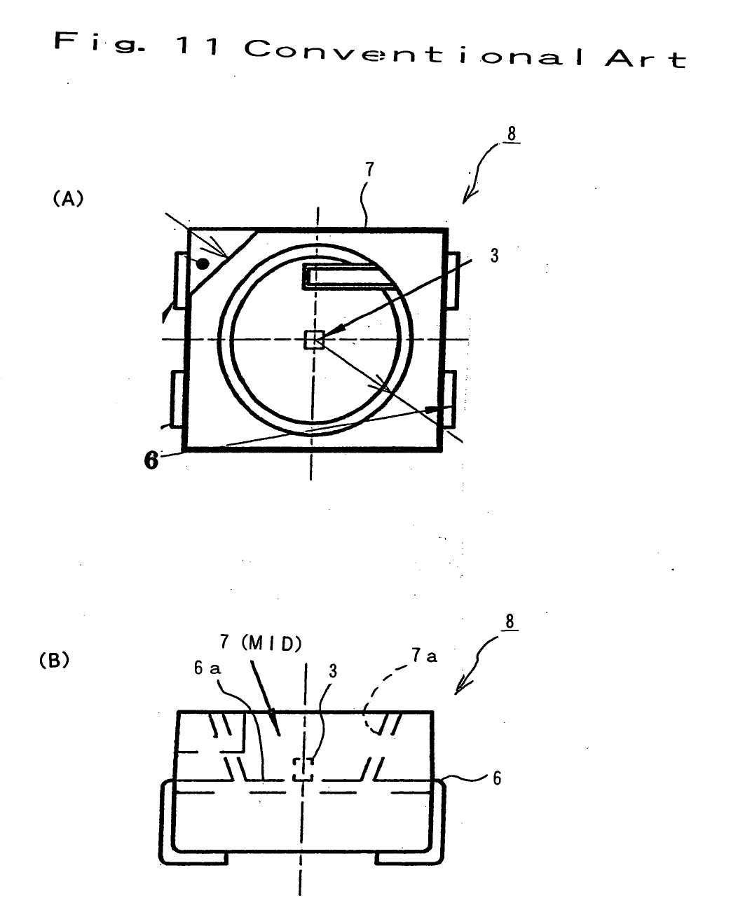

### DESCRIPTION OF PREFERRED EMBODIMENTS

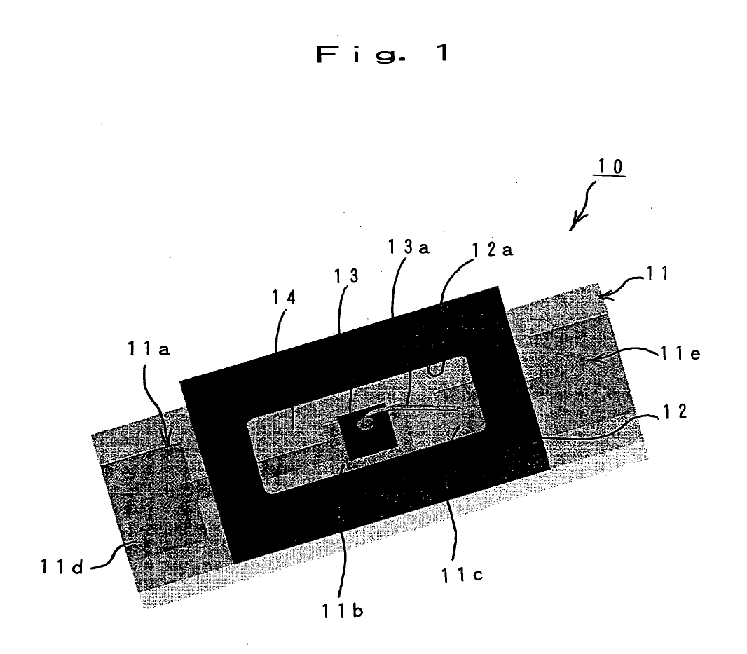

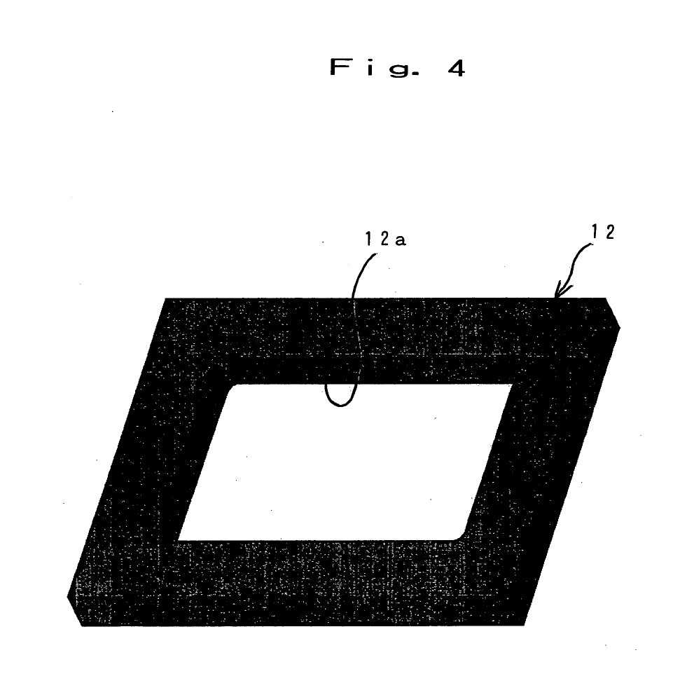

Preferred embodiments of the invention will now be described in detail with reference to FIG. 1 to FIGS. 8A and 8B.

Technically preferred and various features are included in the following embodiments. However, because the embodiments are preferred specific examples of the invention, the scope of the invention is not limited to these aspects and features.

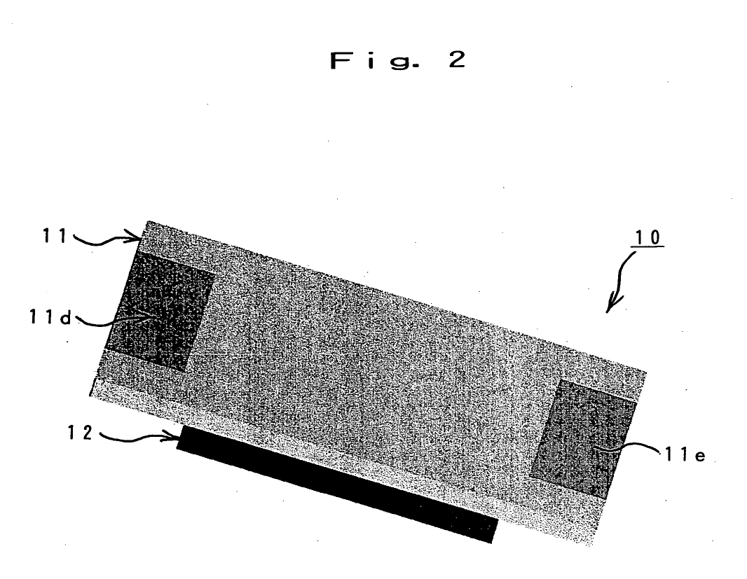

### Embodiment of FIGS. 1 and 2

FIG. 1 and FIG. 2 show a configuration of an embodiment of an LED made in accordance with the principles of the invention. In FIG. 1 and FIG. 2, the LED 10 can consist of or can include a silicon substrate 11, a glass frame 12 disposed on the silicon substrate 11, an LED chip 13 mounted on the silicon substrate 111 in a through-hole 12a of the glass frame 12, and a mold portion filled into the through-hole of the glass frame 12.

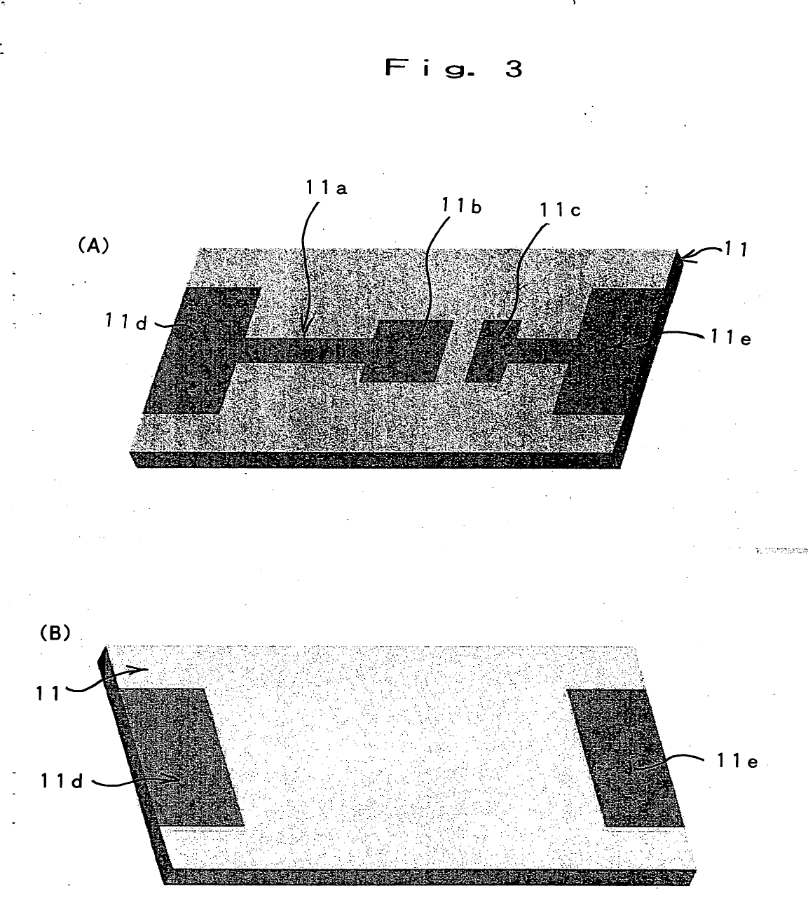

The silicon substrate 11 can consist of or include Si in the form of a plate and, as shown in FIG. 3A and FIG. 3B, a conductive layer 11a with a predefined pattern can be formed on the topside and/or the backside thereof. Near the center of the silicon substrate 11, the conductive layer 11a can include an LED chip equipped portion 11b, a connection land 11c adjacent to this, and electrodes 11d, 11e turning around from both edges to the back side of the silicon substrate 11.

For example, the conductive layer 11 a can be formed as follows. First, after etching and removing a region of the silicon substrate 11 for the conductive layer 11a to be formed, an oxide layer is formed on the entire surface of the silicon substrate 11. Subsequently, a copper pattern is formed by electroforming on the entire surface of the silicon substrate 11. Then, out of the copper pattern, only the region for the conductive layer 11a to be formed is left by removing other portions, for example, with the lithography method. A thin film of Ag/Ni is formed on the entire surface of the left-over copper pattern by sputtering and the like, for example. In this way, the conductive layer 11a is formed.

The glass frame 12 can consist of or include a plate material of borosilicate glass. An opening such as through-hole 12a can be formed at the center by the blast process or the like. The glass frame 12 is integrally held at a predetermined position on the silicon substrate 11 by the so-called anodic bonding or the like.

The LED chip 13 can be an LED chip with a known configuration, which is die-bonded in the through-hole 12a of the glass frame 12 by, for example, eutectic bonding to the LED chip equipped portion 11b on the silicon substrate 11. The top surface of the LED chip can be wire-bonded by a gold wire 13a to the connection land 11c on the silicon substrate 11.

The mold portion 14 can consist of or include a transparent material with a refraction index close to the refraction index of the glass constituting the glass frame 12 (1.52 in the case of borosilicate glass), such as silicone resin. The mold portion can be formed to seal the LED chip 13 by being injected and cured in the through-hole 12a of the glass frame 12.

The LED 10 configured as described above with reference to FIGS. 1-4 can, at the time of manufacture, be manufactured in accordance with the following exemplary method.

First, the conductive layer 11a is formed on the silicon substrate 11. The through-hole 12a can also be processed into the glass frame 12 at this time. Then, the glass frame 12 is fixed to a predetermined position on the silicon substrate 11 by the so-called anodic bonding.

Subsequently, within the through-hole 12a of the glass frame 12, the LED chip 13 is die-bonded onto the LED chip equipped portion 11b of the silicon substrate 11 by eutectic bonding or the like. The top surface of the LED chip 13 can also be wire-bonded to the adjacent connection land 11c via the gold wire 13a.

Finally, the transparent material such as silicone resin is filled and cured in the through-hole 12a of the glass frame 12 to seal the LED chip 13 in the mold portion 14. The LED 10 is then completed.

In operation, by applying an activation voltage to the LED chip 13 via both electrodes 11d, 11e of the silicon substrate 11, the LED chip 13 produces luminescence and light is emitted. Then, the light emitted from the LED chip 13 proceeds within the mold portion 14, and while some of the light is directly emitted to the outside, other portions of the light are emitted laterally through the glass frame 12. In this way, according to this particular embodiment of the LED 10, since the glass frame surrounding the LED chip 13 is constituted by transparent glass which withstands high temperatures during processes (such as bonding of the LED chip 13) and also has high optical transparency, the light emitted from the LED chip 13 is also emitted laterally to the outside. Thus, as is the case with an LED without a conventional lamp house, the LED 10 can generate the light distribution property of the so-called Lambertian distribution. Therefore, the lighting property of the LED 10 appropriately conforms to the optical systems of various equipment into which the LED 10 is incorporated.

On this occasion, since the transparent material such as the silicone resin constituting the mold portion 14 has a refraction index close to the refraction index of the glass constituting the glass frame, almost no reflection or refraction is generated at the interface between the mold portion 14 and the glass frame 12. Also, since the heat generated by the LED chip 13 is conducted efficiently to the mount substrate of the LED 10 via the silicone substrate with relatively high thermal conductivity, the luminous efficiency is not reduced due to the increased temperature of the LED chip 13.

Further, since the transparent material filled into the through-hole 12a of the glass frame 12 in this example is silicone resin, if the occupied area of the LED chip 13 is increased because the LED chip 13 becomes larger or the number of the LED chips 13 is increased, the stress of the silicone resin constituting the mold portion 14 is relatively small and may not generate the distortions such as cracks and warpage in the mold portion 14. Thus, the quality of the LED 10 can easily be maintained since deterioration does not exist due to the use of light with a short wavelength (e.g., ultraviolet light) in the case of sealing with conventional epoxy resin.

In this example, since the electrodes 11d, 11e are exposed on the topside and the backside at both edges of the silicon substrate 11, the LED 10 can be mounted to the mount substrate by both mount methods of top-side bonding and bottom-side bonding, for example. In addition, the LED 10 can be mounted by pressure-bonding for fixing the backside electrodes 11d, 11e to contacts such as connectors.

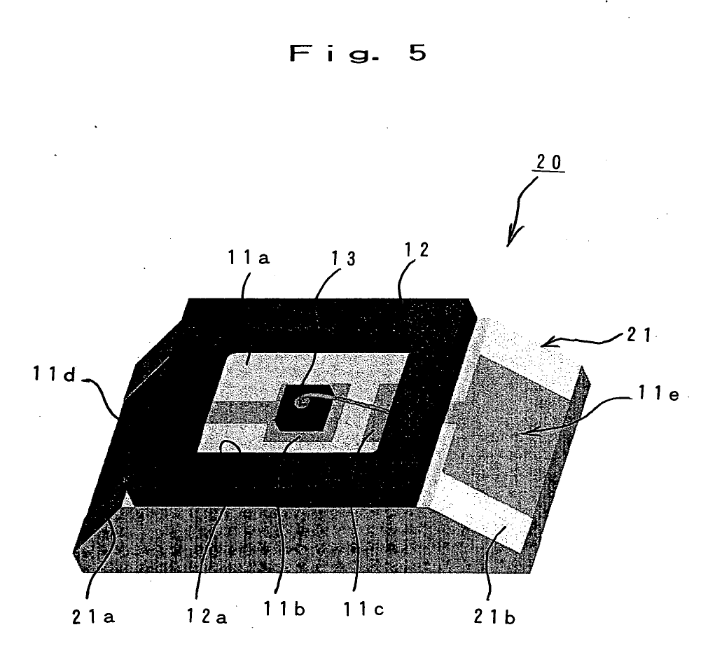

### Embodiment of FIG. 5

FIG. 5 shows another embodiment of the LED made in accordance with the principles of the present invention.

In FIG. 5, the LED 20 has almost the same configuration as the LED 10 shown in FIG. 1 and FIG. 2. Accordingly, the same symbols are used to denote the same or substantially similar elements and the description thereof is omitted.

As compared to the LED 10 shown in FIG. 1 and FIG. 2, the configuration of the LED 20 is different in that the LED 20 is provided with a silicon substrate 21 instead of the silicon substrate 11. The silicon substrate 21 can be constituted by Si in the form of a somewhat thick plate and provided with slant faces 21a, 21b which are lowered outwardly on the surface of both edges. These slant face 21a, 21b may be formed via a cutting process by dicing, for example, or by making the surface of the silicon substrate 21 as a (100) face and making a (110) face as a slant face with alkali wet etching of the KOH system, for example.

Then, the conductive layer 11b described above is formed on the silicon substrate 21. In this case, the electrodes 11d, 11e of the conductive layer 11b are formed only on the slant face 21a, 21b of the silicon substrate 21.

In operation, by applying an activation voltage to the LED chip 13 from both electrodes 21d, 21e of the silicon substrate 21, the LED chip 13 produces luminescence and light is emitted. Then, the light emitted from the LED chip 13 proceeds within the mold portion 14, and while some of the light is directly emitted to the outside, other portions of the light may be emitted laterally through the glass frame 12. In this way, the LED 20 is operated similar to the LED 10.

In this case, since the electrodes 11d, 11e are exposed on the slant face 21a, 21b at both edges of the silicon substrate 21, a mount substrate can be used in which the LED 20 can be electrically connected to contacts on the mount surface side by soldering, pressure-bonding or the like.

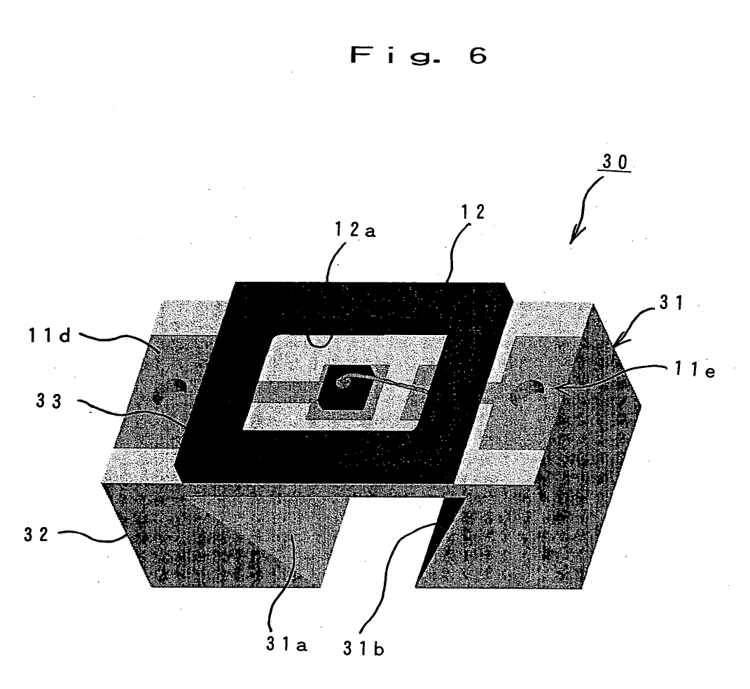

### Embodiment of FIG. 6

FIG. 6 shows another embodiment of the LED made in accordance with the principles of the present invention.

In FIG. 6, the LED 30 has almost the same configuration as the LED 10 shown in FIG. 1 and FIG. 2. Accordingly, the same symbols are used to denote substantially the same elements and the description thereof is omitted.

As compared to the LED 10 shown in FIG. 1 and FIG. 2, the configuration of the LED 30 is different in that the LED 30 is provided with a silicon substrate 31 instead of the silicon substrate 11. The silicon substrate 31 can be constituted by Si and a trapezoidal gap can be provided on the backside with diaphragm surfaces 31a, 31b which extend from the center of the backside to both edges.

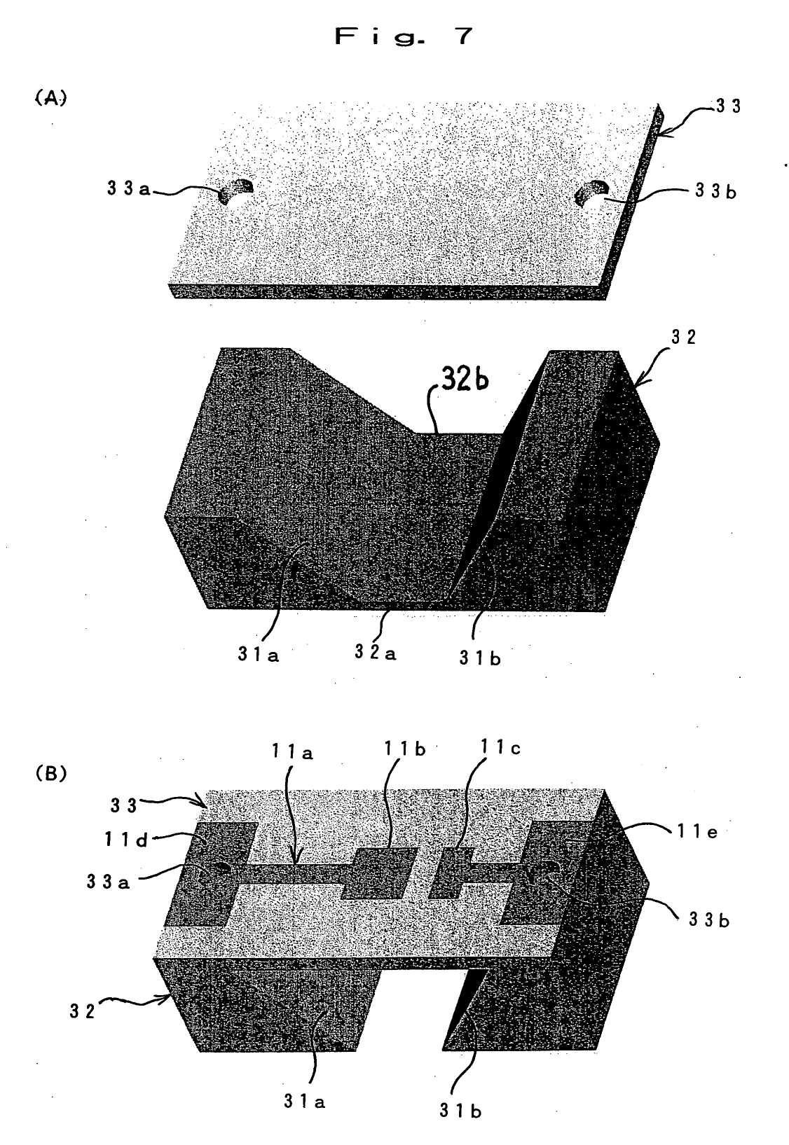

As shown in FIG. 7A, this silicon substrate 31 can consist of or include a lower part 32 forming the diaphragm surfaces 31a, 31b and an upper part 33 in the form of a plate. The silicon substrate 31 can be created by bonding the upper part 33 to the topside of the lower part 32.

The lower part 32 is created by providing a trapezoidal recess 32a in the thick Si plate. For the recess 32a, the diaphragm surfaces 31a, 31b may be formed via a cutting process by dicing, for example, or by making the surface of the Si plate as a (100) face and making a (110) face as a slant face with alkali wet etching of the KOH system, for example, and by sputtering the entire slant face with Au.

The upper part 33 is constituted by Si in the form of the plate with through-holes 33a, 33b near both edges. As shown in FIG. 7B, the silicon substrate 31 is formed by attaching the upper part 33 to the lower part 32 by, for example, Au—Si bonding and by removing a bridge portion 32b connecting the both diaphragm surfaces 31a, 31b by the blast process or the like, for example.

Then, the conductive layer 11b is formed on the silicon substrate 31, as described above. In this case, although the electrodes 11d, 11e of the conductive layer 11b are formed on the surface of both edges of the upper part 33 of the silicon substrate 31, since the electrodes 11d, 11e are also formed within the through-hole 33a, 33b, the electrodes 11d, 11e are also electrically connected to the diaphragm surfaces 31a, 31b of the lower part 32.

In operation, by applying an activation voltage to the LED chip 13 from both electrodes 11d, 11e of the silicon substrate 31, the LED chip 13 produces luminescence and the light is emitted. Then, the light emitted from the LED chip 13 proceeds within the mold portion 14, and while some of the light is directly emitted to the outside, other portions of the light are emitted laterally through the glass frame 12. In this way, the LED 30 is operated similar to the LED 10.

In this case, since the electrodes 11d, 11e are exposed on the surface at both edges of the silicon substrate 21 and the diaphragm surfaces 31a, 31b are electrically connected to the electrodes 11d,11e, the LED 30 can be electrically connected to contacts on a mount surface side by soldering, by pressure-bonding of the diaphragm surfaces 31a, 31b with the buckling of the silicon substrate 31, or the like.

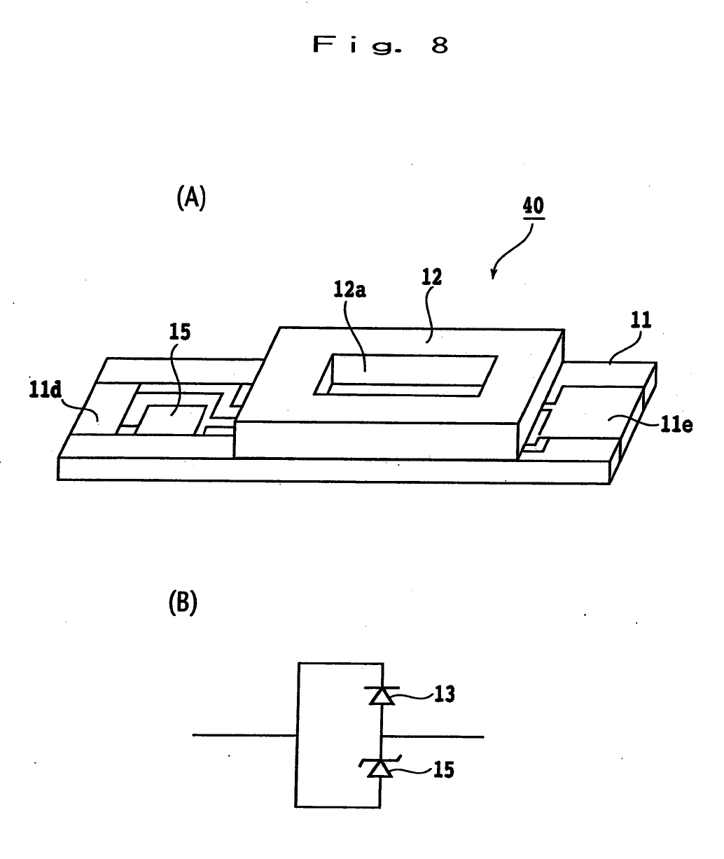

### Embodiment of FIGS. 8A-8B

FIGS. 8A and 8B show another embodiment of the LED made in accordance with the principles of the present invention.

In FIG. 8A, an LED 40 has almost the same configuration as the LED 10 shown in FIG. 1 and FIG. 2. The configuration thereof is different in that the LED 40 is provided with a Zener diode 15 on the silicon substrate 11.

The Zener diode 15 is fabricated with p-type and n-type thin films created by impurity diffusion or the like, for example, on the surface of the silicon substrate 11 in a known manner. A detailed description of the configuration thereof is omitted.

For the Zener diode 15, when the LED chip 13 is die-bonded on the LED chip equipped portion 11, as shown in FIG. 8B, the Zener diode 15 can be connected in parallel with the LED chip 13.

In this way, since the LED chip 13 is protected by maintaining the activation voltage applied to the LED chip 13 because of the action of the Zener diode 15, the LED chip 13 will not be destroyed by an excessive voltage applied to the LED chip 13.

Although the embodiments described above are configured such that the light emitted from the LED chip 13 simply exits to outside via the mold portion 14 and the glass frame 12, the invention is not limited to this and, by dispersing and dispersedly mixing a wavelength conversion material such as fluorescent material in the silicone resin constituting the mold portion 14, the wavelength conversion material can be excited by the light from the LED chip 13 to change a color temperature by converting the wavelength of the light emitted from the LED chip 13. The resulting light having a mixed color of light from the LED chip 13 and excitation light emitted by the wavelength conversion material. For example, white light can be emitted to the outside as the mixed color light by using a blue LED chip as the LED chip 13 and using a fluorescent material that generates yellow light.

Also, in the embodiments described above, although the mold portion 14 is constituted by the silicone resin only, the present invention is not limited to this, and a diffusing agent or other material can be mixed in the silicone resin constituting the mold portion 14. When including a diffusing agent, the light from the LED chip is diffused by the diffusing agent mixed in mold portion 14 and is emitted to the outside via the mold portion 14 and the glass frame 12. Thus, the light emitted from the LED chip has a uniform light distribution property. Therefore, for example, if a plurality of LED chips is provided, when the light from each LED chip is sufficiently diffused by the diffusing agent, the light distribution property can be obtained as if the light is emitted from one (1) light source.

In the embodiment of FIG. 8A and 8B described above, although the Zener diode 15 is fabricated on the silicon substrate 11, the present invention is not limited to this, and it is should be understood that other types of devices such as a current resistance element (CRD) or an activation control circuit of the LED chip 13 such as a flashing circuit may be fabricated on the silicon substrate, for example.

In this way, an extremely excellent LED may be provided such that the light distribution property of the Lambertian distribution can be obtained and distortions such as cracks and warpage due to the stress of the lens portion are reduced or not generated, even if the occupied area of the LED chip is increased.

While the illustrative and presently preferred embodiments of the invention have been described in detail herein, it is to be understood that the inventive concepts may be otherwise variously embodied and employed and that the appended claims are intended to be construed to include such variations except insofar as limited by the prior art.

What is claimed is:

1. An LED comprising:
a silicon substrate, including a conductive pattern having an LED chip equipped portion, a connection portion, and electrodes;
a glass frame anodic-bonded onto the silicon substrate, and including an opening forming a lamp house;
an LED chip mounted adjacent the silicon substrate in the opening of the glass frame; and
a mold portion of silicone resin located in the opening of the glass frame.

2. The LED of claim 1, wherein the silicon substrate has a top light emitting side and a backside, and the electrodes are located at the backside of the silicon substrate.

3. The LED of claim 1, wherein the silicon substrate includes at least one of a side face and a laterally-facing slant face, and at least one of the electrodes is located at at least one of the side face and the laterally-facing slant face.

4. The LED of claim 1, wherein the silicon substrate includes a trapezoidal diaphragm surface and at least one of the electrodes is located at the diaphragm surface.

5. The LED of claim 1, wherein the silicone resin constituting the mold portion has a refraction index that is substantially the same as a refraction index of the glass frame.

6. The LED of claim 1, wherein the glass frame is constituted by borosilicate glass.

7. The LED of claim 1, wherein the conductive pattern formed on the silicon substrate is provided with a portion constituting an additional predetermined circuit.

8. The LED of claim 1, wherein a wavelength conversion material is dispersed in the silicone resin constituting the mold portion.

9. The LED of claim 1, wherein a diffusing agent is mixed in the silicone resin constituting the mold portion.

10. The LED of claim 2, wherein the silicone resin constituting the mold portion has a refraction index that is substantially the same as a refraction index of the glass frame.

11. The LED of claim 3, wherein the silicone resin constituting the mold portion has a refraction index that is substantially the same as a refraction index of the glass frame.

12. The LED of claim 4, wherein the silicone resin constituting the mold portion has a refraction index that is substantially the same as a refraction index of the glass frame.

13. The LED of claim 2, wherein the glass frame is constituted by borosilicate glass.

14. The LED of claim 3, wherein the glass frame is constituted by borosilicate glass.

15. The LED of claim 4, wherein the glass frame is constituted by borosilicate glass.

16. The LED of claim 2, wherein the conductive pattern formed on the silicon substrate is provided with a portion constituting an additional predetermined circuit.

17. The LED of claim 3, wherein the conductive pattern formed on the silicon substrate is provided with a portion constituting an additional predetermined circuit.

18. The LED of claim 4, wherein the conductive pattern formed on the silicon substrate is provided with a portion constituting an additional predetermined circuit.

19. The LED of claim 2, wherein a wavelength conversion material is dispersed in the silicone resin constituting the mold portion.

20. The LED of claim 3, wherein a wavelength conversion material is dispersed in the silicone resin constituting the mold portion.

21. The LED of claim 4, wherein a wavelength conversion material is dispersed in the silicone resin constituting the mold portion.

22. The LED of claim 2, wherein a diffusing agent is mixed in the silicone resin constituting the mold portion.

23. The LED of claim 3, wherein a diffusing agent is mixed in the silicone resin constituting the mold portion.

24. The LED of claim 4, wherein a diffusing agent is mixed in the silicone resin constituting the mold portion.

25. The LED of claim 1, wherein the electrodes are external electrodes.

26. The LED of claim 1, wherein the opening in the glass frame is a through hole opening.

27. The LED of claim 1, wherein the mold portion consists of silicone resin.

28. The LED of claim 8, wherein the wavelength conversion material is a fluorescent material.
